(19) United States
(12) Patent Application Publication
(10) Pub. No.: US 2017/0271230 A1
(43) Pub. Date: Sep. 21, 2017

(54) MANUFACTURING METHOD OF MOLDED PRODUCT AND MOLDED PRODUCT

(71) Applicant: FUJI ELECTRIC CO., LTD., Kanagawa (JP)

(72) Inventor: Yuki INABA, Matsumoto-city (JP)

(21) Appl. No.: 15/445,996

(22) Filed: Mar. 1, 2017

(30) Foreign Application Priority Data
Mar. 18, 2016 (JP) 2016-055688

(51) Int. Cl. H01L 23/31; H01L 23/528; H01L 21/56; B29C 45/14; B29C 45/00

(52) U.S. Cl. CPC H01L 23/3121; B29C 45/14639; B29C 45/14065; B29C 45/0046; H01L 21/56; H01L 23/5283; B29K 2995/0005; B29L 2031/3406

(57) ABSTRACT

Provided is a molded product manufacturing method, including attachment of attaching a partially exposed member that extends from inside a sealed portion in the molded product to be exposed to outside to a sealing target member that is to be sealed inside the sealed portion in the molded product; injecting of inserting the sealing target member having the partially exposed member attached thereto in a die and injecting a sealing material into the die; adjustment of, in a first time period during which the sealing material is injected, holding the partially exposed member at a position differing from a final position in the molded product and adjusting a flow of the sealing material with an adjusting member attached to the partially exposed member; and hardening the sealing material after the first time period.

The contents of the following Japanese patent application are incorporated herein by reference:
NO. 2016-055688 filed in JP on May 18, 2016.

### BACKGROUND

1. Technical Field

The present invention relates to a molded product and a molded product manufacturing method.

2 Related Art

A molded product of a semiconductor device is known that is formed by mounting a semiconductor element on a conductive pattern or an insulating substrate having a conductive pattern and sealing this structure with resin, as shown in Patent Documents 1 and 2, for example. In order to prevent the occurrence of voids inside the molded product, technology is known for securing a member that determines the fluidity of the resin to a sealed member, as shown in Patent Documents 3 to 6 and 14, for example, and for changing the fluidity of the resin by deforming a metal die, as shown in Patent Documents 4 to 13, for example.
Patent Document 1: International Publication WO 2011-83737
Patent Document 2: Japanese Patent Application Publication No. 2014-57005
Patent Document 3: Japanese Patent Application Publication No. 2008-311558
Patent Document 4: Japanese Patent No. 3006285
Patent Document 5: Japanese Patent No. 5217039
Patent Document 6: Japanese Patent No. 5613100
Patent Document 7: Japanese Patent Application Publication No. 2000-3923
Patent Document 8: Japanese Patent Application Publication No. 2005-310831
Patent Document 9: Japanese Patent Application Publication No. 2010-149423
Patent Document 10: Japanese Patent Application Publication No. 2012-139821
Patent Document 11: Japanese Patent Application Publication No. 2014-175336
Patent Document 12: Japanese Patent Application Publication No. 2014-218038
Patent Document 13: Japanese Patent No. 3784684
Patent Document 14: Japanese Patent Application Publication No. 2003-115505

However, technology is desired for reliably preventing the occurrence of voids using a simple configuration.

### SUMMARY

Therefore, it is an object of an aspect of the innovations herein to provide a molded product and a molded product manufacturing method, which are capable of overcoming the above drawbacks accompanying the related art. The above and other objects can be achieved by combinations described in the claims. According to a first aspect of the present invention, provided is a molded product manufacturing method, comprising attachment of attaching a partially exposed member that extends from inside a sealed portion in the molded product to be exposed to outside to a sealing target member that is to be sealed inside the sealed portion in the molded product; injecting of inserting the sealing target member having the partially exposed member attached thereto in a die and injecting a sealing material into the die; adjustment of, in a first time period during which the sealing material is injected, holding the partially exposed member at a position differing from a final position in the molded product and adjusting a flow of the sealing material with an adjusting member attached to the partially exposed member; and hardening the sealing material after the first time period.

According to a second aspect of the present invention, provided is a molded product comprising a sealing material; a sealing target member sealed inside the sealing material; and a partially exposed member that is attached to the sealing target member inside the sealing material and extends from inside the sealing material to be exposed to outside. The sealing target member includes an adjusting member for adjusting a flow of the sealing material before hardening, attached to the partially exposed member.

The summary clause does not necessarily describe all necessary features of the embodiments of the present invention. The present invention may also be a sub-combination of the features described above.

### BRIEF DESCRIPTION OF THE DRAWINGS

FIG. 1A is a perspective view of a molded product according to an embodiment of the present invention.

FIG. 1B shows a cross-sectional configuration of the molded product relating to the reference line AA shown in FIG. 1A.

FIG. 2 is a flow chart showing a manufacturing method of the molded product according to the present embodiment.

FIG. 3A shows the relationship between the positions of the pins and the flow speed of the unhardened resin.

FIG. 3B shows the relationship between the positions of the pins and the flow speed of the unhardened resin.

FIG. 3C shows the relationship between the positions of the pins and the flow speed of the unhardened resin.

FIG. 4 shows a cross-sectional configuration of the molded product relating to the reference line BB shown in FIG. 1A.

FIG. 5 is a perspective view of the adjusting member.

FIG. 6A shows a cross-sectional shape of an adjusting member according to a modification.

FIG. 6B shows a cross-sectional shape of an adjusting member according to a modification.

FIG. 6C shows a cross-sectional shape of an adjusting member according to a modification.

FIG. 6D shows a cross-sectional shape of an adjusting member according to a modification.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

### 1. The First Embodiment

(1-1. Outline of the Semiconductor Module)

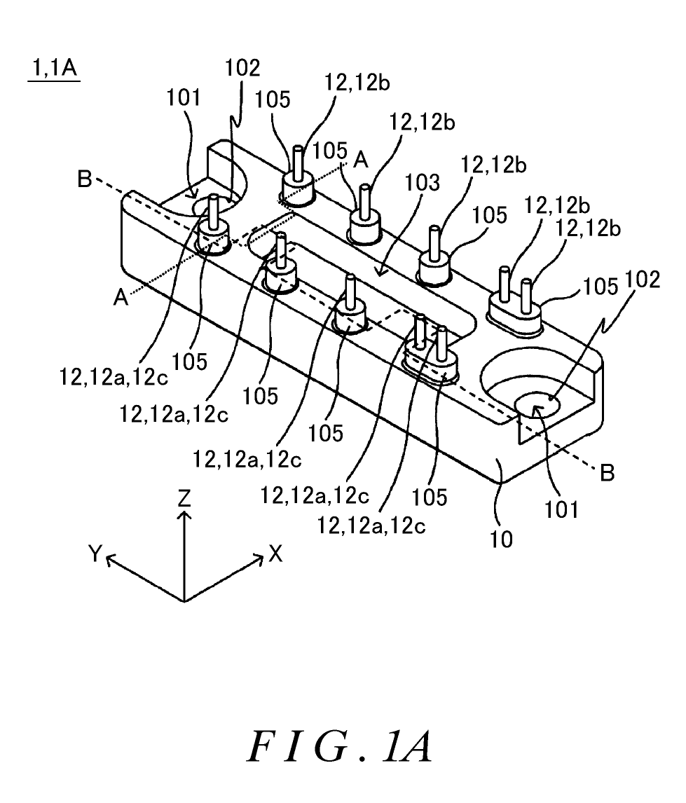

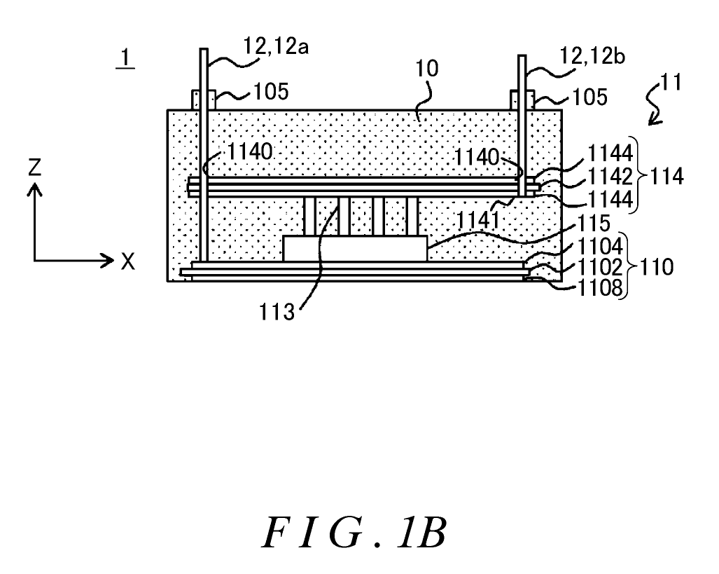

FIG. 1A is a perspective view of a semiconductor module 1 according to an embodiment of the present invention. FIG. 1B shows a cross-sectional configuration of the semiconductor module 1 relating to the reference line AA shown in FIG. 1A. In this Specification, the X direction and the Y direction are perpendicular to each other, and the Z direction is perpendicular to the X-Y plane. The semiconductor module 1 of the present embodiment has a top surfaces facing in the +Z direction and a bottom surface facing the −Z direction. In other words, terms such as “up” and “above” refer to the +Z direction. In contrast, terms such as “down” and “below” refer to the −Z direction.

In the present embodiment, the occurrence of voids is prevented by adjusting the flow of a sealing material by holding a partially exposed member that extends from inside the sealed portion in the semiconductor module, which is an example of a molded product, to the outside the sealed portion such that this partially exposed member is at a position differing from a final position during at least a partial time period during the molding.

The semiconductor module 1 is an example of the molded product, and includes the sealing material 10, one or more sealing target members 11 that are sealed inside the sealing material 10, and one or more pins 12 for electrically connecting to the outside. For example, the semiconductor module 1 according to the present embodiment is a switching apparatus that switches between a conductive state and a non-conductive state between main terminals according to control input to a control terminal.

Here, the switching apparatus has a unique threshold voltage, conducts electricity between two pins 12 upon receiving a switching voltage greater than or equal to the threshold voltage to, and stops the conduction upon receiving a switching voltage that is greater than or equal to the threshold voltage. In an opposite manner, the switching apparatus may conduct electricity between the two pins 12 upon receiving a switching voltage that is less than the threshold voltage, and stop the conduction upon receiving a switching voltage greater than or equal to the threshold voltage. A plurality of the switching apparatuses may be used by being connected in parallel.

(1-1-1. The Sealing Material)

The sealing material 10 may be a hardened resin, and seals the sealing target member 11 described further below. The sealing material 10 may form a main body portion of the semiconductor module 1. For example, the sealing material 10 is molded with a substantially rectangular parallelepiped shape with a longitudinal direction in the Y direction, by performing molding, preferably transfer molding, using an insulating thermosetting resin such as an epoxy resin or maleimide resin. A polyimide resin, an isocyanate resin, an amino resin, a phenol resin, a silicon-type resin, or another thermosetting resin may be used as the sealing material 10. The sealing material 10 may further contain an additive such as an inorganic filler.

A stepped portion 101 that is substantially semicircular in an overhead view and a hole 102 passing through the stepped portion 101 in the Z direction are formed at each end of the sealing material 10 in the Y direction. By inserting securing jigs such as bolts into the holes 102 from above, it is possible to secure the semiconductor module 1 to an external apparatus or the like.

A concave portion 103 extending in the Y direction may be formed in the center of the top surface of the sealing material 10, and pillar-shaped convex portions 105 may be arranged along the Y direction respectively on one side and another side of the concave portion 103 in the X direction in a manner to sandwich the concave portion 103. The pins 12 described further below may protrude upward as seen from the top surfaces of the convex portions 105. The pins 12 may protrude upward from the top surface of the sealing material 10 without having the convex portions 105 provided on this top surface, or the concave portion may be provided in the top surface of the sealing material 10 and the pins 12 may protrude upward from this concave portion.

(1-1-2. The Sealing Target Member)

The one or more sealing target members 11 in the present embodiment include one or more insulating substrates 110, one or more semiconductor elements 115, one or more conducting posts 113, and one or more print substrates 114, for example.

(1-1-2(1). The Insulating Substrate)

Each insulating substrate 110 is arranged in a bottom portion of the sealing target member 11, for example. As an example, each insulating substrate 110 is arranged perpendicular to the Z direction. In the present embodiment, as an example, a plurality of the insulating substrates 110 are provided along the Y direction.

The insulating substrates 110 are DCB (Direct Copper Bonding) substrates, AMB (Active Metal Blazing) substrates, or the like, for example. The insulating substrates 110 may have one or more of the pins 12 described further below established thereon. Each insulating substrate 110 includes an insulating board 1102 and one or more conducting layers 1104 formed on the top surface of the insulating board 1102. Each insulating substrate 110 may further include a thermal transfer layer 1108 formed on the bottom surface of the insulating board 1102.

The insulating board 1102 is an insulating board-shaped member, and is formed from an insulating ceramic such as aluminum nitride, silicon nitride, or aluminum oxide, for example. The insulating board 1102 may be a board-shaped member formed from a resin insulating material, glass material, or the like. The insulating board 1102 provides electrical insulation between the conducting layer 1104 and the thermal transfer layer 1108.

The conducting layer 1104 and the thermal transfer layer 1108 are each formed using a conductive metal such as copper or aluminum, for example. Among these layers, the conducting layer 1104 includes a wire pattern for connecting to the semiconductor element 115. The thermal transfer layer 1108 allows heat to escape to the bottom surface side from the insulating board 1102 side on the top surface. The bottom surface of the thermal transfer layer 1108 may be exposed in the bottom surface of the sealing material 10.

(1-1-2(2). The Semiconductor Element)

Each semiconductor element 115 is mounted on a conducting layer 1104. Each semiconductor element 115 may be a power MOSFET (Metal Oxide Semiconductor Field Effect Transistor) or an IGBT (Insulated Gate Bipolar Transistor), or may be an FWD (Free Wheeling Diode). The semiconductor elements 115 may be RB-IGBTs (Reverse Blocking IGBTs) or RC-IGBTs (Reverse Conducting IGBTs) formed in a vertical direction inside one chip and including electrodes respectively on the front surface and back surface.

As an example, each semiconductor element 115 may be a vertical switching element formed from a semiconductor such as Si, SiC, or GaN, and may include electrodes respectively on the front and back surfaces. In a case where a semiconductor element 115 includes an electrode on the back surface side, the semiconductor element 115 may be affixed on the insulating substrate 110 by connecting the electrode on the back surface side to the conducting layer 1104 with a bonding agent such as solder. In a case where a semiconductor element 115 includes an electrode on the front surface side, the conducting post 113 described further below may be electrically connected to this electrode on the front surface side.

The semiconductor module 1 according to the present embodiment includes three semiconductor elements 115, but may instead include one or two semiconductor elements 115 or four or more semiconductor elements 115. The plurality of semiconductor elements 115 may be connected in series with each other, or may be connected in parallel. By connecting a plurality of the same type of semiconductor elements 115 in parallel, it is possible to increase the rated output capable of being processed in the semiconductor module 1. Furthermore, the plurality of semiconductor elements 115 may each be a different type of element. For example, the plurality of semiconductor elements 115 may include IGBT semiconductor elements 115 and FWD semiconductor elements 115 connected in parallel with each other.

(1-1-2(3). The Conducting Post)

Each conducting post 113 is provided between a semiconductor element 115 and a print substrate 114 described further below. The conducting post 113 is a member for thermally and electrically connecting the semiconductor element 115 and the print substrate 114, and is molded as a cylindrical pillar using metal with low electrical resistance and a high thermal transfer rate, such as copper or aluminum, for example. The conducting post 113 is established on the semiconductor element 115 by connecting the bottom end of the conducting post 113 to the semiconductor element 115 with a bonding agent such as solder, and the top end of the conducting post 113 is electrically connected to the print substrate 114 by solder, brazing, or caulking. Instead of or in addition to the conducting post 113 shaped as a cylindrical pillar, an internal connecting portion with another arbitrary shape, such as a board-shaped lead frame or block-shaped conducting terminal, may be used.

(1-1-2(4). The Print Substrate)

Each print substrate 114 is provided above the insulating substrate 110 and faces the insulating substrate 110, and is electrically connected to a semiconductor element 115. For example, each print substrate 114 may be perpendicular to the Z direction. Furthermore, the distance between the top surface of a sealed portion sealed by the sealing material 10 and the top surface of a print substrate 114 may be greater than the distance between the bottom surface of the print substrate 114 and the top surface of the insulating substrate 110. For example, the print substrate 114 may be arranged between the top surface of the sealing material 10 and the top surface of the insulating substrate 110, on a side closer to the insulating substrate 110. This print substrate 114 connects an electrode of a semiconductor element 115 to one or more pins 12 described further below.

Each print substrate 114 includes an insulating board 1142 and a conducting layer 1144 formed on the front and back surfaces of the insulating board 1142. The insulating board 1142 can adopt a rigid substrate formed from a glass epoxy material or the like or a flexible substrate formed from a polyimide material or the like. The insulating board 1142 in the present embodiment may be a flexible substrate that has flexibility.

A hole 1140 for passing the pin 12 described further below that is pressed is provided in the insulating board 1142. The conducting layer 1144 includes a wire pattern formed using a conductive metal such as aluminum. This wire pattern electrically connects each conducting post 113 connected to a front surface electrode of a semiconductor element 115 to the corresponding pin 12.

The print substrate 114 is an example of a flexible board-shaped member that functions as an adjusting member for adjusting the flow of the sealing material 10 before hardening. For example, the print substrate 114 may function to adjust the flow of the sealing material 10 in a side of the print substrate 114 opposite the insulating substrate 110, i.e. the top surface side. This function is described in detail further below.

(1-1-3. The Pin)

Each pin 12 is a terminal for providing an electrical connection between a semiconductor element 115 and/or print substrate 114 and the outside, is attached to the sealing target member 11 inside the sealing material 10, and extends from inside the sealing material 10 to be exposed to the outside. As an example, each pin 12 is arranged parallel to the Z direction, and the pins 12 are provided in parallel at each X-direction end portion. Each pin 12 may be molded as a cylindrical pillar or square pillar, using a conductive metal such as copper or aluminum, for example. Each pin 12 may be formed as another shape, such as a board shape or block shape.

In the present embodiment, as an example, the plurality of pins 12 include one or more pins 12a established on the conducting layer 1104 of the insulating substrate 110 and one or more pins 12b established on the print substrate 114.

Each pin 12a is established on the conducting layer 1104 of the insulating substrate 110, extends upward, is pressed into a hole 1140 of the print substrate 114, and protrudes from a convex portion 105 on the top surface of the sealing material 10. The bottom end portion of each pin 12 may be thermally and electrically connected to the conducting layer 1104 by solder. As an example, the bottom end portion of each pin 12 may be inserted into a concave portion (not shown) formed in the conducting layer 1104.

Each pin 12a is connected to an electrode of a semiconductor element 115, e.g. a back surface side electrode, via the conducting layer 1104, and/or electrically connected to a front surface side electrode of a semiconductor element 115 via a conducting post 113 and the conducting layer 1144 of the print substrate 114.

Each pin 12b is established on the print substrate 114, extends upward, and protrudes from a convex portion 105 on the top surface of the sealing material 10. The bottom surface of each pin 12 may be thermally and electrically connected to the conducting layer 1144 by solder. As an example, the bottom end portion of each pin 12b may be pressed into a hole 1140 of the print substrate 114, or may be pressed into a concave portion (not shown in the drawings) formed in the conducting layer 1144. Each pin 12b may be connected to a front surface side electrode of the semiconductor element 115 via a conducting post 113 and the conducting layer 1144 of the print substrate 114.

Each connecting portion between the bottom end portion of a pin 12b and a hole 1140 may be adhered with an epoxy resin or the like, for example. In this way, when force is applied to a pin 12b in a state where the sealing material 10 has been removed from the semiconductor module 1, it is possible to prevent the pins 12b from being removed from the insulating board 1142. Each connection portion between the bottom end portion of a pin 12a and a hole 1140 may be adhered in the same manner.

The plurality of pins 12 including the pins 12a and 12b may function as any one of an output terminal, a source (emitter) terminal, a drain (collector) terminal, and a gate (base) terminal of the semiconductor module 1 functioning as a switching apparatus. One or more of the plurality of pins 12 may be electrically connected to an interface member that is not shown in the drawings.

The interface member may include an external output terminal, a print substrate for signal wires, and a print substrate for power supply wires. The external output terminal may be connected to one or more of the pins 12 functioning as an output terminal, and may be provided on a side surface portion of the semiconductor module 1 in the X direction. The print substrate for the signal wires may be electrically connected to one or more of the pins 12 serving as a gate (base) terminal.

The print substrate for the power supply wires may include a print substrate in which a P-side conductive board electrically connecting one or more of the pins 12 functioning as a drain (collector) terminal and a positive electrode and an N-side conductive board electrically connecting one or more of the pins 12 functioning as a source (emitter) terminal and a negative terminal are layered in a manner to face each other and be insulated from each other. The P-side conductive board and the N-side conductive board may each extend in the Y direction and cover all of the pins 12 in the semiconductor module 1, and may include notches at positions opposite the one or more pins 12 that are not connected to the board, through which these pins 12 pass.

Here, one or more of the pins 12b established on the conducting layer 1144 of the print substrate 114 and electrically connecting the print substrate 114 and an external device are examples of partially exposed members. This pin 12b is attached to the print substrate 114 at a position enabling the print substrate 114 to bend in the surface direction by applying a force to the pin 12b in a state where the sealing material 10 is removed from the semiconductor module 1.

For example, the pins 12b may be attached at positions closer to the downstream side and/or the upstream side in the direction of the flow of the sealing material 10 from among the positions in the print substrate 114 during the molding. As an example, the pins 12b may be attached at positions approximately 1 cm toward the downstream side from positions opposite the semiconductor element 115 that is farthest downstream in the molding die, from among each position in the print substrate 114. Furthermore, a pin 12b may be attached at a position approximately 1 cm toward the downstream side from the position that is farthest downstream, except for the connecting portion for the pin 12b, in the wire pattern of the conducting layer 1144, from among each position in the print substrate 114.

Preferably, the pins 12b are attached to the end portion 1141 of the print substrate 114. In this way, by applying a force to the pins 12b in the Z direction in a state where the sealing material 10 has been removed from the semiconductor module 1, e.g. the state before the molding, the print substrate 114 bends in a direction of the normal line thereof, e.g. the Z direction, and the end portion 1141 can move in the Z direction. In this way, the print substrate 114 functions as an adjusting member for adjusting the flow of the sealing material 10 before hardening.

With the semiconductor module 1 described above, the print substrate 114 included in the sealing target member 11 is attached to the pins 12b and adjusts the flow of the unhardened sealing material 10. Accordingly, when forming the semiconductor module 1, in a first time period during which the unhardened resin of the sealing material 10 is injected, the pins 12b are held at positions differing from the final positions and the flow of the unhardened resin can be adjusted by the print substrate 114. Accordingly, it is possible to adjust the flow speed and inflow state of the unhardened resin at each position in the die. This print substrate 114 functions as an electrical circuit that transfers an electrical signal between the pins 12b during actual operation after the sealing. In this way, the occurrence of voids can be reliably prevented with a simple configuration. The final positions of the pins 12b are the positions of the pins 12b in the semiconductor module 1. Holding the pins 12b at positions differing from the final positions may include securing the pins 12b at these positions or causing the pins 12b to swing at these positions.

(1-2. The Semiconductor Module Manufacturing Method)

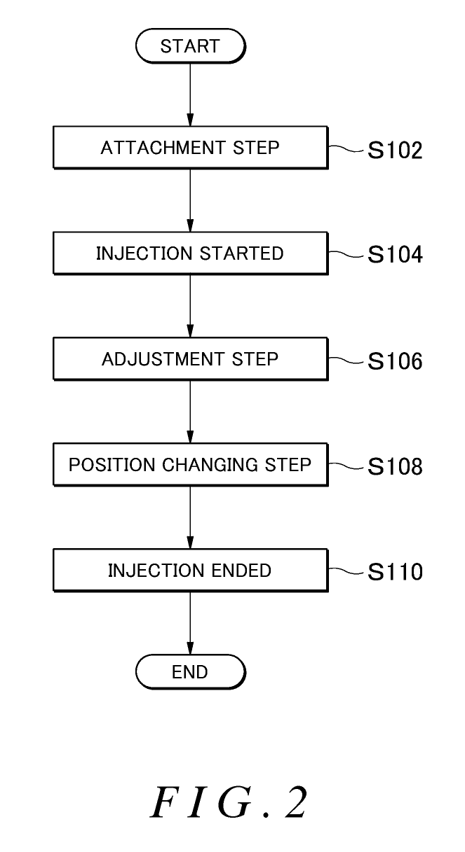

FIG. 2 is a flow chart showing a manufacturing method of the semiconductor module 1 according to the present embodiment. In the present embodiment, as an example, the resin injection direction is in the X direction of FIG. 1B, the side (−X side) near the injection side is the upstream side, and the side (+X side) far from the injection side is the downstream side. Furthermore, as an example, the cross-sectional area of the bottom side of the print substrate 114 in the semiconductor module 1 is less than the cross-sectional area of the top side of the print substrate 114. Instead, the cross-sectional area of the top side may be less than the cross-sectional area of the bottom side.

When manufacturing the semiconductor module 1, first, the one or more pins 12 are attached to the sealing target member 11 (S102). For example, one or more pins 12b established on the print substrate 114 may be attached at positions closer to the downstream side in the print substrate 114. As an example, the pins 12b may be attached to the end portion 1141 by being pressed into the holes 1140 of the print substrate 114. In this way, the semiconductor module 1 in a state where the sealing material 10 has been removed may be formed. The pins 12b may be attached to the end portion on the upstream side of the print substrate 114, or may be attached to the end portions on both the upstream side and the downstream side.

Next, the sealing target member 11 to which the one or more pins 12 have been attached is inserted into the die, and the injection of the unhardened resin of the sealing material 10 is started (S104). For example, the semiconductor module 1 in the state where the sealing material 10 has been removed may be inserted into the molding die. A transfer molding die may be used as the molding die.

When inserting the sealing target member 11 into the die, the sealing target member 11 may be arranged such that the distance between the top surface of the print substrate 114 and the die is greater than the distance between the bottom surface of the print substrate 114 and the top surface of the insulating substrate 110. For example, the sealing target member 11 may be arranged such that the cross-sectional area of the flow path of the unhardened resin in the top space of the print substrate 114 is greater than the cross-sectional area of the flow path in the bottom space of the print substrate 114, i.e. the space between the print substrate 114 and the insulating substrate 110.

Furthermore, one or more of the pins 12b and the end portion 1141 of the print substrate 114 may be arranged at positions closer to the downstream side in the direction in which the sealing material 10 flows, among the positions in the molding die. The sealing target member 11 may be arranged such that one or more of the pins 12b extend outward from the molding die. The sealing target member 11 may be arranged such that the entire sealing target member 11 is secured inside the die.

When injecting the sealing material 10 into the die, the unhardened resin of the sealing material 10 may be injected from a position farther from the one or more pins 12b and the print substrate 114 among the positions in the molding die. For example, the temperature of the unhardened resin and the molding die may be set such that the unhardened sealing material 10 being injected hardens in approximately 1 minute while flowing to the downstream side inside the die. As an example, when using an epoxy resin, for a metal die in a range from approximately 100° C. to 180° C. at which the hardening reaction of the epoxy resin does not progress in the molding process, unhardened resin with a temperature approximately from 30° C. to 50° C. and a viscosity less than or equal to approximately 20 Pa·s may be injected into the die. Preferably, unhardened resin with a viscosity of approximately 20 Pa·s is injected into a metal die at a temperature of 180° C.

Next, in the first time period during which the sealing material 10 is being injected, by holding the one or more pins 12b at one or more positions differing from the final positions in the semiconductor module 1, the flow of the sealing material 10 is adjusted by the print substrate 114 having the pins 12b attached thereto (S106).

Here, the first time period may be set in advance from the process of S104 described above to the process of S108 described further below. Furthermore, the final positions of the pins 12b are the positions of the pins 12b in the semiconductor module 1, e.g. the positions of the pins 12b in a state where the print substrate 114 is not bent in the surface direction. As long as the characteristics of the semiconductor module 1 are in an allowable range, the positions of the pins 12b in a state where the print substrate 114 is bent may be the final positions.

At S106, by applying a force to the pins 12b and bending the print substrate 114 in the surface direction, for example, the print substrate 114 may be made to function as an adjusting member for the flow of the unhardened resin. Furthermore, by applying a force to the plurality of pins 12b and twisting the print substrate 114, the print substrate 114 may be made to function as the adjusting member. As an example, a force in the positive or negative Z direction may be applied to the pins 12b in a manner to push or pull these pins 12b. A force may be applied in another direction in a manner to tilt the pins 12b.

The flow speed of the sealing material 10 on the top surface side of the print substrate 114 may be adjusted, for example. As an example, the cross-sectional area of the flow path of the unhardened resin in the top space of the print substrate 114 may be made larger or smaller. Preferably, the flow speed of the unhardened resin on the top surface side of the print substrate 114 may be limited. For example, when attaching pins 12b to the end portion of the print substrate 114 on the upstream side, by moving the pins 12b upward, it is possible to limit the flow speed of the unhardened resin on the top surface side of the print substrate 114 and to increase the amount of the unhardened resin flowing through the bottom space of the print substrate 114. When attaching pins 12b to the end portion of the print substrate 114 on the downstream side as well, the same effects can be obtained by moving the pins 12b upward.

The holding positions of the pins 12b and the length of the first time period may be the positions and the length in a case where a plurality of semiconductor modules 1 are created as samples while setting various positions for each pin 12b at each timing after the injection is started and a semiconductor module 1 that does not include voids is manufactured.

Furthermore, at least one of the inflow state and flow speed of the unhardened resin may be monitored at least at one location in the die, for example, and the positions of one or more of the pins 12b may be further changed to other positions differing from the final positions according to the monitoring results. The first time period may be ended according to the monitoring results.

The monitoring technique is, for example, a technique of providing one or more temperature sensors (not shown in the drawings) at one or more locations in the die and monitoring the output signal output by each temperature sensor. Each temperature sensor may be exposed in the inner surface of the die and directly detect the temperature of the resin in the die, or may be provided inside the die and indirectly detect the temperature of the resin in the die from the temperature of the die. With the output signal of this temperature sensor, it is possible to monitor the position at which the injected resin arrives by detecting a position where the temperature drops from among the plurality of positions in the die. Furthermore, it is possible to monitor the flow speed of the unhardened resin by detecting the movement speed at the position where the temperature drops.

The technique for changing the positions of the one or more pins 12b according to the monitoring results is, for example, a technique of, when the distance from the injection inlet of the unhardened resin is the same but there is a temperature difference between temperature sensors, the positions of the one or more pins 12b are changed such that the flow speed of the unhardened resin is lowered at the position of the temperature sensor detecting the lower temperature. Furthermore, this technique is, for example, a technique of setting a target value in advance for the temperature at each timing after the injection is started for a plurality of temperature sensor positions, and changing the positions of one or more of the pins 12b such that the flow speed is increased at a position where the temperature is higher than the target value and the flow speed is decreased at a position where the temperature is lower than the target value. As the target values for the temperature at the plurality of temperature sensor positions, a temperature profile obtained in a case where a plurality of semiconductor modules 1 are created as samples while setting various positions for of each pin 12b at each timing after the injection is started and a semiconductor module 1 that does not include voids is manufactured may be used.

The technique for ending the first time period according to the monitoring results is, for example, a technique of ending the first time period when there is a difference in the temperature change timing between temperature sensors on the downstream side that are the same distance from the injection inlet of the unhardened resin, i.e. when it is estimated that the arrival timings of the unhardened resin are the same.

Next, the one or more pins 12b are arranged at the final positions in the semiconductor module 1 (S108). For example, the print substrate 114 returns to a state of not being bent. A force may be applied to the pins 12b to arrange the pins 12b at the final positions. This process of S108 may be performed immediately before the injection of the unhardened resin is completed. The pins 12b and the print substrate 114 may be arranged at the final positions by the pressure of the resin by releasing the hold on the pins 12b at S106 without performing the process of S108.

The injection is completed and the unhardened resin in the die is hardened (S110). In this way, the semiconductor module 1 is manufactured.

With the manufacturing method described above, in the first time period during which the unhardened resin of the sealing material 10 is injected, after the pins 12b are held at positions differing from the final positions and the flow of the unhardened resin is adjusted by the print substrate 114, the pins 12b are arranged at the final positions, and therefore it is possible to adjust the inflow state and the flow speed of the unhardened resin at each position in the die. Accordingly, it is possible to reliably prevent the occurrence of voids with a simple structure, without adding movable structures to the metal die or the like.

(1-3. The Relationship Between the Positions of the Pins 12b and the Flow Speed of the Unhardened Resin)

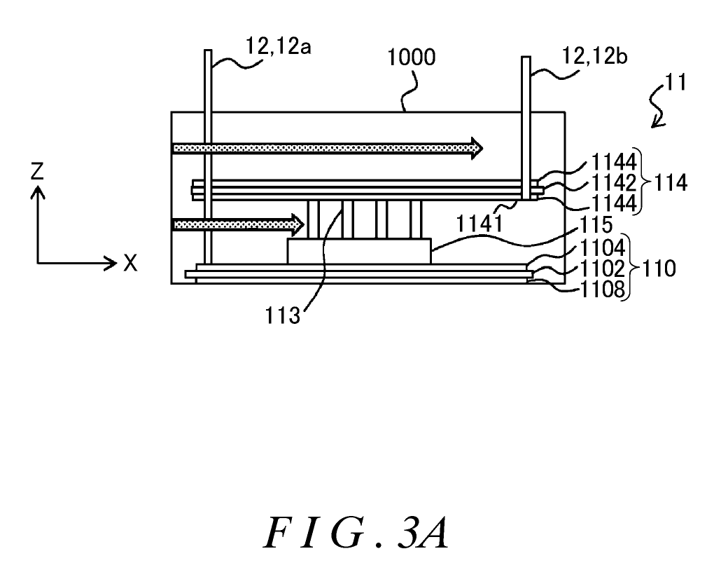

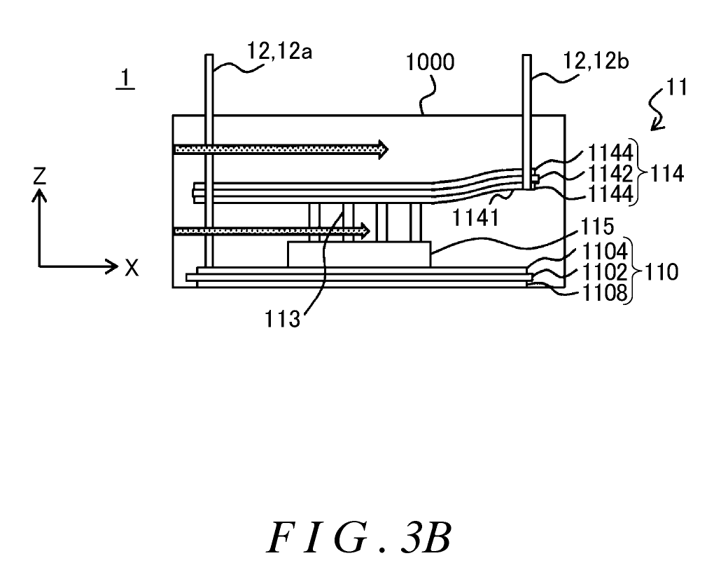

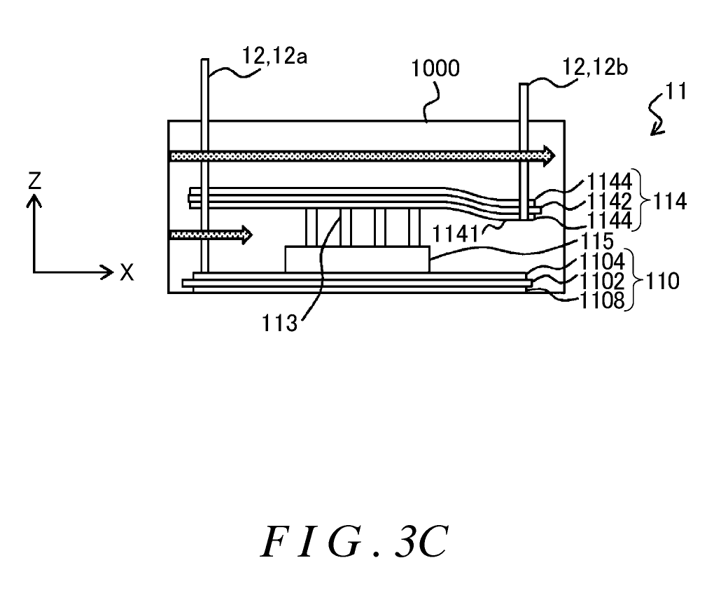

FIGS. 3A to 3C show the relationship between the positions of the pins 12b and the flow speed of the unhardened resin, when the unhardened resin of the sealing material 10 is being injected into a die 1000. More specifically, FIG. 3A shows the flow speed of the unhardened resin when the pins 12b are held at the final positions, e.g. when force is not applied to the pins 12b, in the first time period. FIG. 3B shows the flow speed of the unhardened resin when the pins 12b are held at positions farther up than the final positions in the first time period. FIG. 3C shows the flow speed of the unhardened resin when the pins 12b are held at positions farther down than the final positions in the first time period. In FIGS. 3A to 3C, display of the die portion for forming the stepped portion 101, the hole 102, the concave portion 103, and the convex portion 105 is omitted.

As shown in FIG. 3A, when the pins 12b are held at the final positions in the first time period, the flow speed of the unhardened resin in the top space of the print substrate 114 is greater than the flow speed of the unhardened resin in the bottom space of the print substrate 114 (see the shaded arrows). Therefore, the unhardened resin flowing in the bottom space and the unhardened resin that flows through the top space to circulate in the bottom space from the end portion of the die 1000 on the downstream side flow together near the semiconductor element 115 on the downstream side position in the bottom space to form a well drain. Defects such as voids are easily formed in the well drain.

The semiconductor module manufactured in this manner is a comparative example of the semiconductor module 1 according to the present embodiment. Upon observing this semiconductor module using X-ray transmission observation, it was found that voids occurred around the semiconductor element 115 at a rate of approximately 50%.

As shown in FIG. 3B, when the pins 12b are held at positions farther up than the final positions in the first time period, the flow speed of the unhardened resin in the top space of the print substrate 114 is approximately the same as the flow speed of the unhardened resin in the bottom space of the print substrate 114 (see the shaded arrows). Therefore, the unhardened resin flowing through the bottom space and the unhardened resin flowing through the top space flow together farther on the downstream side of the die 1000 than the sealing target member 11 and form a well drain.

The semiconductor module manufactured in this manner is an embodiment example of the semiconductor module 1 according to the present embodiment. Upon observing this semiconductor module 1 using X-ray transmission observation, it was found that voids occurred at a rate of 0% in the semiconductor module 1.

As shown in FIG. 3C, when the pins 12b are held at positions farther down than the final positions in the first time period, the flow speed of the unhardened resin in the top space of the print substrate 114 is significantly greater than the flow speed of the unhardened resin in the bottom space of the print substrate 114 (see the shaded arrows). Therefore, the unhardened resin flowing through the bottom space and the unhardened resin that has flowed through the top space to circulate in the bottom space from the end portion of the die 1000 on the downstream side flow together near the semiconductor element 115 and the like positioned in the bottom space and form a well drain.

The semiconductor module manufactured in this manner is a comparative example of the semiconductor module 1 according to the present embodiment. Upon observing this semiconductor module using X-ray transmission observation, it was found that voids occurred in the bottom portion of the print substrate 114 and around the semiconductor element 115 at a rate of approximately 100%.

### 2. The Second Embodiment

(2-1. The Basics of the Semiconductor Module)

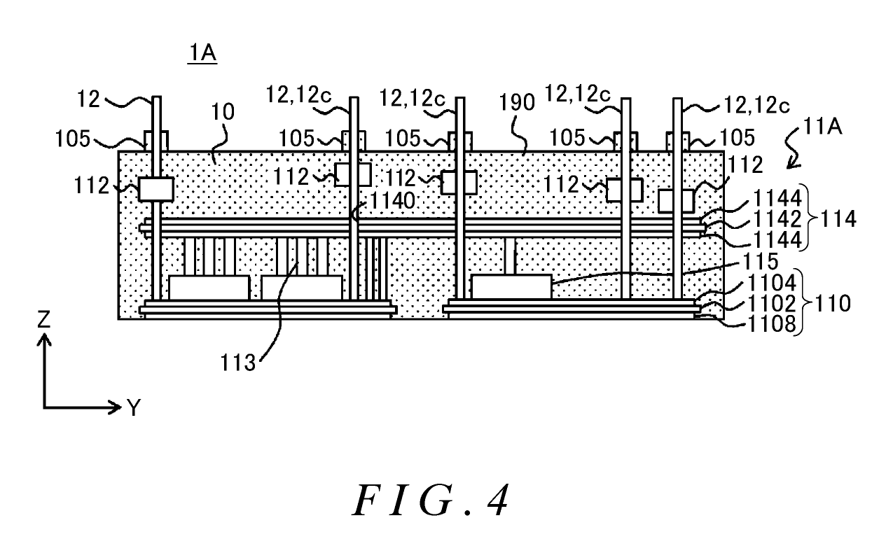

FIG. 4 shows a cross-sectional configuration of a semiconductor module 1A relating to the reference line BB shown in FIG. 1A. As shown in the drawing, the semiconductor module 1A according to the present embodiment includes one or more pins 12c as at least a portion of the pins 12 and one or more sealing target members 11A instead of the sealing target member 11. The semiconductor module 1A may include the one or more pins 12b in the first embodiment and the one or more pins 12c.

The one or more pins 12c are examples of rod-shaped members. This pin 12c is a circular pillar that is electrically connected to and rotatably attached to the insulating substrate 110 and/or the print substrate 114 serving as an example of a board-shaped member, in a state where the sealing material 10 is removed.

For example, the bottom end portion of the pin 12c is pressed into a hole 1140 of the print substrate 114 or the concave portion (not shown in the drawings) formed in the conducting layer 1104 of the insulating substrate 110. Furthermore, at least one of a contact region contacting at least the insulating board 1142 in the circumferential side surface of the pin 12c and the inner circumferential surface of the hole 1140 may be coated with a material having better toughness than the insulating board 1142. In this way, when the pin 12c rotates relative to the insulating board 1142 in a state where the sealing material 10 has been removed from the semiconductor module 1, it is possible to prevent the insulating board 1142 from being damaged.

For example, when the circumferential side surface of the pin 12c is coated, the coating may be performed using a conductive material with a high thermal transfer rate. As an example, the circumferential side surface of the pin 12c may be plated with the same type of metal as the pin 12c, or may be plated with a different metal (e.g. solder) than the pin 12c.

When the inner circumferential surface of the hole 1140 is coated, the coating may be performed using an insulating material with a high thermal transfer rate. As an example, the inner circumferential surface of the hole 1140 may be coated with a resin.

The one or more sealing target members 11A include one or more adjusting members 112 for adjusting the flow of the sealing material 10 before hardening, and the one or more adjusting members 112 are attached to the one or more pins 12c. The adjusting member 112 may be rotatable according to the axial rotation of the pin 12c in a state where the sealing material 10 has been removed from the semiconductor module 1. The adjusting member 112 may function in a manner to adjust the flow of the sealing material 10 on the side of the print substrate 114 opposite the insulating substrate 110, e.g. the top surface side. As an example, the adjusting member 112 may be positioned above the print substrate 114, and is preferably positioned near the print substrate 114.

One adjusting member 112 may be attached to each pin 12c, or a plurality of adjusting members 112 may be attached to each pin. Among the plurality of pins 12c, the adjusting member 112 may be attached to just one of these pins 12c.

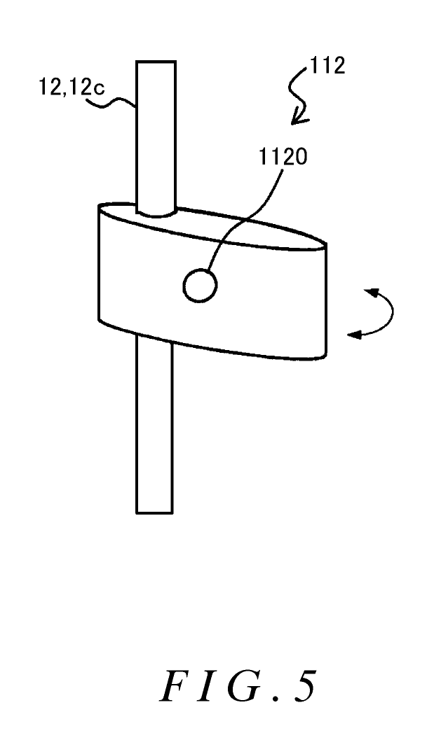

FIG. 5 is a perspective view of an adjusting member 112. The adjusting member 112 may have a board shape with an orientation that changes according to the rotation of the pin 12c. For example, the cross-sectional shape of the adjusting member 112 perpendicular to the Z direction may be a shape in which the length differs according to the direction of a straight line passing through the rotational center, e.g. an elliptical shape with the rotational center provided at the end portion. From the perspective of avoiding the focus of stress after the unhardened resin of the sealing material 10 has hardened, the corners of the adjusting member 112 are preferably chamfered.

The adjusting member 112 may include, in a circumferential side surface thereof, at least one opening 1120 through which a portion of the unhardened resin of the sealing material 10 passes during molding. For example, the opening 1120 may pass the unhardened resin when the adjusting member 112 is orthogonal or substantially orthogonal to the flow direction of the unhardened resin. In this case, it is possible to make the resin flow in a region adjacent to the adjusting member 112 on the downstream side, and therefore it is possible to prevent the occurrence of voids.

The adjusting member 112 may be formed integrally with the pin 12c. For example, the adjusting member 112 may be formed integrally with the pin 12c using the metal material of the pin 12c.

The adjusting member 112 may be formed by the same material as the sealing material 10. For example, the adjusting member 112 may be formed using an insert molding technique to arrange the pin 12c inside the die and form the adjusting member 112 with the same material as the sealing material 10.

(2-2. The Semiconductor Module Manufacturing Method)

The semiconductor module 1A is manufactured using the same manufacturing method as used for the semiconductor module 1 described above in relation to FIG. 2.

It should be noted that, when manufacturing the semiconductor module 1A, in the process of S102, the one or more pins 12c are rotatably attached to the insulating substrate 110 and/or the print substrate 114 in the sealing target member 11A. The pins 12c may be provided on the downstream side, on the upstream side, or on both the downstream side and upstream side with respect to the flow of the unhardened resin. One or more non-rotatable pins 12 may further be attached to the insulating substrate 110 and/or the print substrate 114.

Each adjusting member 112 may be arranged such that the depths at which the adjusting members 112 are positioned in the sealed portion are different from each other between the plurality of pins 12c. For example, the adjusting members 112 may be arranged at higher positions when farther upstream in the direction in which the unhardened resin of the sealing material 10 flows, and arranged at lower positions, i.e. closer to the print substrate 114, when farther downstream. In an opposite manner, the adjusting members 112 may be arranged at lower positions, i.e. closer to the print substrate 114, when farther upstream, and arranged at higher positions when farther downstream.

In order to prepare pins 12c provided with the adjusting members 112 arranged at desired depths, the adjusting members 112 are provided in advance respectively at different positions of pins 12c having the same shape, for example, and the pins 12c to which the adjusting members 112 at the desired positions are provided may be selected. Furthermore, by providing an adjusting member 112 in a middle portion of an elongated pin 12c and cutting off both ends of this pin 12c, the pin 12c provided with the adjusting member 112 at the desired position may be formed. Yet further, the adjusting members 112 may be provided to the pins 12c in a manner to be slidable, and the adjusting members 112 may be moved to the desired positions.

In the process of S106, each pin 12c may be held at a rotational position differing from the final rotational position in the rotational direction, in the first time period during which the sealing material 10 is injected. In this way, as a result of the adjusting members 112 being held at rotational positions differing from the final rotational positions, the flow of the sealing material 10 is adjusted.

Here, the final rotational positions of the pins 12c are rotational positions of the pins 12c in the semiconductor module 1, for example, and are rotational positions of the pins 12c in a state where the adjusting members 112 are oriented along the direction of the flow of the unhardened resin, for example. Holding the pins 12c at rotational positions differing from the final rotational positions may mean securing the pins 12c at these rotational positions or causing the pins 12c to swing at these rotational positions, for example.

At S106, for example, the flow speed of the sealing material 10 on the top surface side of the print substrate 114 may be adjusted. As an example, the cross-sectional area of the flow path of the unhardened resin on the top surface side of the print substrate 114 may be made larger or made smaller. Preferably, the flow speed of the unhardened resin on the top surface side of the print substrate 114 may be limited.

As the rotational positions held for the pins 12c and the length of the first time period, the rotational positions and the length in a case where a plurality of semiconductor modules 1 are created as samples while setting various rotational positions for each pin 12c at each timing after the injection is started and a semiconductor module 1 that does not include voids is manufactured.

For example, at least one of the inflow state and the flow speed of the unhardened resin at least at one location in the die may be monitored in the same manner as in the first embodiment, and the rotational positions of the one or more pins 12c may be further changed to other positions differing from the final rotational positions according to the monitoring results. Furthermore, the first time period may be ended according to the monitoring results.

The technique for changing the rotational positions of the one or more pins 12c according to the monitoring results is, for example, a technique of, when there is a temperature difference between temperature sensors at the same distance from the injection inlet of the unhardened resin, the rotational positions of the one or more pins 12c are changed such that the flow speed of the unhardened resin is lowered at the position of the temperature sensor detecting the lower temperature. Furthermore, this technique is, for example, a technique of setting a target value in advance for the temperature at each timing after the injection is started for a plurality of temperature sensor positions, and changing the rotational positions of one or more of the pins 12c such that the flow speed is increased at a position where the temperature is higher than the target value and the flow speed is decreased at a position where the temperature is lower than the target value. As the target values for the temperature at the plurality of temperature sensor positions, a temperature profile obtained in a case where a plurality of semiconductor modules 1 are created as samples while setting various rotational positions for of each pin 12c at each timing after the injection is started and a semiconductor module 1 that does not include voids is manufactured may be used.

In the process of S108, the pins 12c may be rotated to the final rotational positions. The pins 12c may be arranged at the final rotational positions by applying a force to the pins 12c, or by releasing the hold on the pins 12c at S106.

With the manufacturing method described above as well, it is possible to adjust the inflow state and the flow speed of the unhardened resin at each position in the die, and therefore it is possible to reliably prevent the occurrence of voids with a simple structure.

(2-3. Modifications of the Adjusting Member)

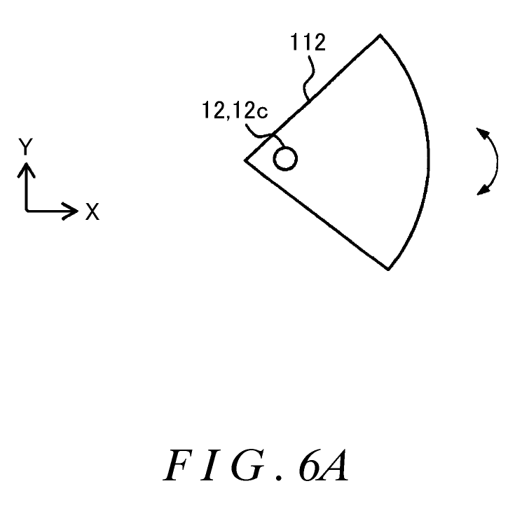

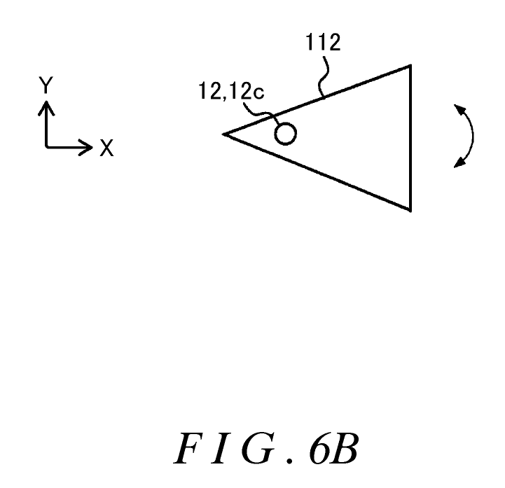

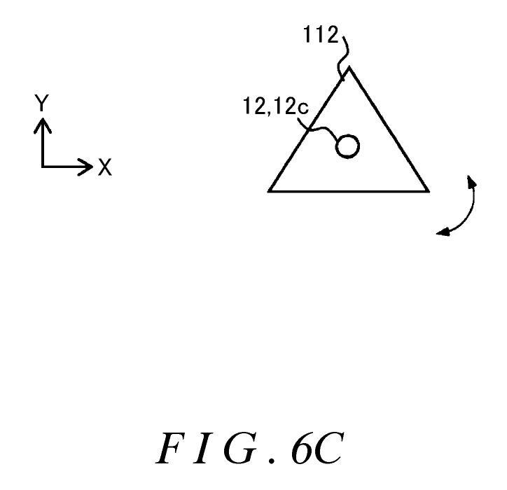

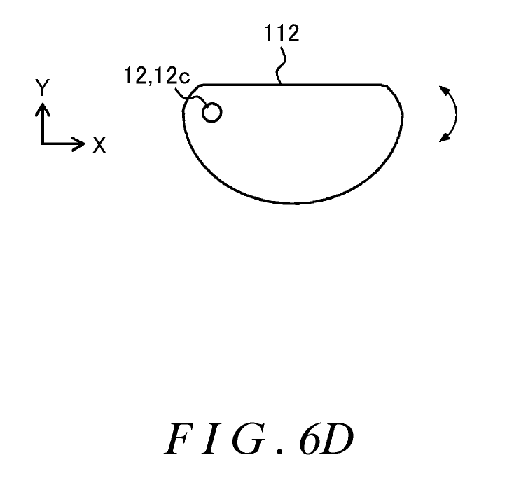

FIGS. 6A to 6D show cross-sectional shapes of adjusting members 112 according to modifications. As shown in the drawings, the cross-sectional shape of the adjusting member 112 perpendicular to the Z direction can assume a variety of shapes, as long as the length in a direction of a straight line passing through the rotational center is different.

For example, the cross-sectional shape of the adjusting member 112 perpendicular in the Z direction may be a partial circular shape, as shown in FIG. 6A, or may be a polygonal shape such as a triangle, as shown in FIGS. 6B and 6C. Here, the rotational center of the adjusting member 112 may be a position shifted from the center, as shown in FIGS. 6A and 6B, or may be a central position in the cross-sectional shape, as shown in FIG. 6C. In a case where the rotational center is at a position shifted from the center of the cross-sectional shape, the adjustment amount of the flow of the unhardened resin becomes larger.

The cross-sectional shape of the adjusting member 112 may have a width that becomes greater as the distance from the rotational center increases, as shown in FIGS. 6A and 6B. In this case, when the long side surface among the side surface of the adjusting member 112 is made to face the flow of the unhardened resin to limit this flow, the space farther on the downstream side than this side surface is filled with the adjusting member 112 itself. For example, in a board-shaped adjusting member 112 where the width is constant regardless of the distance from the rotational center, when the long side surface is made to face the flow, a region is created on the downstream side of the adjusting member 112 where it is difficult for the resin to flow. In contrast, with the adjusting member 112 shown in FIG. 6B, for example, such a region in which it is difficult for the resin to flow is filled by the adjusting member 112 itself. Therefore, the occurrence of voids is prevented on the downstream side of the adjusting member 112.

The cross-sectional shape of the adjusting member 112 perpendicular to the Z direction may be an arbitrary shape differing from a partially circular shape and polygonal shape, as shown in FIG. 6D. The cross-sectional shape of the adjusting member 112 may be asymmetric relative to any straight line passing through the rotational center.

### 3. Modifications of the First and Second Embodiments

In the first and second embodiments described above, the molded product is described as a semiconductor module 1, but may instead be an arbitrary molded product such as a molded product that does not include a semiconductor element, a molded product that does not include an electrical circuit, a product in which a terminal or the like is insert-molded (such as a resin case), or a plastic model product, for example.

The partially exposed member that is exposed to the outside and attached to the sealing target member 11 is described as pins 12b that electrically connect the semiconductor element 115 and/or the print substrate 114 to an external device, but may instead be a member having another function.

In the first embodiment described above, the adjusting member is described as a print substrate 114, but instead of or in addition to this, the adjusting member may be a flexible board-shaped member that bends up and down according to force being applied to the pins 12 in a state where the sealing material 10 has been removed. Such a board-shaped member may be an insulating substrate 110, or may be another board-shaped member attached to the print substrate 114 and having pins 12 established thereon.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

As made clear from the above, with an embodiment of the present invention, it is possible to realize a manufacturing method of a molded product that reliably prevents the occurrence of voids.

What is claimed is:

1. A molded product manufacturing method, comprising:
attachment of attaching a partially exposed member that extends from inside a sealed portion in the molded product to be exposed to outside to a sealing target member that is to be sealed inside the sealed portion in the molded product;
injecting of inserting the sealing target member having the partially exposed member attached thereto in a die and injecting a sealing material into the die;
adjustment of, in a first time period during which the sealing material is injected, holding the partially exposed member at a position differing from a final position in the molded product and adjusting a flow of the sealing material with an adjusting member attached to the partially exposed member; and
hardening the sealing material after the first time period.

2. The manufacturing method according to claim 1, wherein
the sealing target member includes a flexible board-shaped member,
the attachment includes attaching the partially exposed member to the board-shaped member, and
the adjustment includes causing the board-shaped member to function as the adjusting member by applying a force to the partially exposed member to bend the board-shaped member in a surface direction.

3. The manufacturing method according to claim 2, wherein
the attachment includes attaching a plurality of the partially exposed members to the board-shaped member, and
the adjustment includes causing the board-shaped member to function as the adjusting member by applying a force to the plurality of partially exposed members to twist the board-shaped member.

4. The manufacturing method according to claim 2, wherein
the partially exposed member is attached to the board-shaped member at a position closer to a downstream side in a direction of a flow of the sealing material.

5. The manufacturing method according to claim 2, wherein
the board-shaped member is a print substrate, and
the partially exposed member is a pin for electrically connecting the print substrate and an external device of the molded product.

6. The manufacturing method according to claim 1, wherein
the partially exposed member includes a rod-shaped member,
the sealing target member includes the adjusting member that is attached to the rod-shaped member and rotates according to axial rotation of the rod-shaped member, and
the adjustment includes holding the rod-shaped member at a rotational position differing from a final rotational position in a rotational direction.

7. The manufacturing method according to claim 6, wherein
the adjusting member has a board shape with an orientation that changes according to rotation of the rod-shaped member.

8. The manufacturing method according to claim 6, wherein
the adjusting member has a cross-sectional shape perpendicular to a length direction of the rod-shaped member, with a length that differs according to a direction of a straight line passing through a rotational center.

9. The manufacturing method according to claim 6, wherein
the adjusting member includes at least one opening through which a portion of the sealing material passes.

10. The manufacturing method according to claim 6, wherein
the adjusting member is formed integrally with the rod-shaped member.

11. The manufacturing method according to claim 6, wherein
the adjusting member is formed of the same material as the sealing material.

12. The manufacturing method according to claim 6, wherein
the attachment includes attaching a plurality of the rod-shaped members to the sealing target member, and
the plurality of rod-shaped members have different depth positions from each other for the adjusting member in the sealed portion.

13. The manufacturing method according to claim 6, wherein
the sealing target member includes a board-shaped member, and
the attachment includes attaching the rod-shaped member in a rotatable manner to the board-shaped member.

14. The manufacturing method according to claim 13, wherein
the board-shaped member is a print substrate, and
the rod-shaped member is a pin for electrically connecting the print substrate and an external device.

15. The manufacturing method according to claim 5, wherein
the sealing target member further includes an insulating substrate that has an insulating board with a conducting layer formed on a top surface and a semiconductor element mounted on the conducting layer,
the print substrate is provided facing the insulating substrate above the insulating substrate and is electrically connected to the semiconductor element, and
the adjustment includes adjusting a flow speed of the sealing material in the print substrate on a side opposite the insulating substrate.

16. The manufacturing method according to claim 15, wherein
a distance between the top surface of the print substrate and a die is greater than a distance between a bottom surface of the print substrate and the top surface of the insulating substrate, and
the adjustment includes limiting the flow speed of the sealing material in the top surface side of the print substrate.

17. The manufacturing method according to claim 14, wherein
the sealing target member further includes an insulating substrate that has an insulating board with a conducting layer formed on a top surface and a semiconductor element mounted on the conducting layer,
the print substrate is provided facing the insulating substrate above the insulating substrate and is electrically connected to the semiconductor element, and
the adjustment includes adjusting a flow speed of the sealing material in the print substrate on a side opposite the insulating substrate.

18. The manufacturing method according to claim 17, wherein
a distance between a top surface of the print substrate and a die is greater than a distance between a bottom surface of the print substrate and the top surface of the insulating substrate, and
the adjustment includes limiting the flow speed of the sealing material in the top surface side of the print substrate.

19. The manufacturing method according to claim 1, wherein the adjustment includes:
monitoring at least one of an inflow state and a flow speed of the sealing material at least at one location in the die, and
changing a position of the partially exposed member according to a result of the monitoring.

20. The manufacturing method according to claim 19, wherein
the adjustment includes monitoring an output signal output by at least one temperature sensor provided at least at one location on the die.

21. The manufacturing method according to claim 1, comprising:
position changing of, after the first time period, arranging the partially exposed member at a final position in the molded product.

22. A molded product comprising:
a sealing material;
a sealing target member sealed inside the sealing material; and
a partially exposed member that is attached to the sealing target member inside the sealing material and extends from inside the sealing material to be exposed to outside, wherein
the sealing target member includes an adjusting member for adjusting a flow of the sealing material before hardening, attached to the partially exposed member.

23. The molded product according to claim 22, wherein
the sealing target member includes a flexible board-shaped member that functions as the adjusting member, and
the partially exposed member is attached to the board-shaped member at a position enabling the board-shaped member to bend in a surface direction, by applying a force in a state where the sealing material has been removed.

24. The molded product according to claim 23, wherein
the board-shaped member is a print substrate, and
the partially exposed member is a pin for electrically connecting the print substrate and an external device.

25. The molded product according to claim 22, wherein
the partially exposed member includes a rod-shaped member,
the sealing target member includes the adjusting member that is attached to the rod-shaped member and can rotate according to axial rotation of the rod-shaped member, in a state where the sealing material has been removed.

26. The molded product according to claim 25, wherein
the sealing target member further includes a board-shaped member, and
the partially exposed member is attached to the board-shaped member in a manner to be rotatable relative to the board-shaped member in a state where the sealing material has been removed.

27. The molded product according to claim 26, wherein
the board-shaped member is a print substrate, and
the rod-shaped member is a pin for electrically connecting the print substrate to an external device.

28. The molded product according to claim 24, wherein
the sealing target member further includes an insulating substrate that has an insulating board with a conducting layer formed on a top surface and a semiconductor element mounted on the conducting layer,
the print substrate is provided facing the insulating substrate above the insulating substrate and is electrically connected to the semiconductor element, and
the adjusting member is for adjusting a flow of the sealing material in the print substrate on a side opposite the insulating substrate.

29. The molded product according to claim 28, wherein
a distance between a top surface of a sealed portion formed by the sealing material in the molded product and a top surface of the print substrate is greater than a distance between a bottom surface of the print substrate and a top surface of the insulating substrate, and
the adjusting member is for limiting a flow speed of the sealing material in the top surface side of the print substrate.

30. The molded product according to claim 27, wherein
the sealing target member further includes an insulating substrate that has an insulating board with a conducting layer formed on a top surface and a semiconductor element mounted on the conducting layer,
the print substrate is provided facing the insulating substrate above the insulating substrate and is electrically connected to the semiconductor element, and
the adjusting member is for adjusting a flow of the sealing material in the print substrate on a side opposite the insulating substrate.

31. The molded product according to claim 30, wherein
a distance between a top surface of a sealed portion formed by the sealing material in the molded product and a top surface of the print substrate is greater than a distance between a bottom surface of the print substrate and a top surface of the insulating substrate, and
the adjusting member is for limiting a flow speed of the sealing material in the top surface side of the print substrate.

32. The molded product according to claim 22, wherein
the partially exposed member is held at a position differing from a final position in the molded product, the flow of the sealing material is adjusted by the adjusting member, and the sealing material is injected and hardened.
